(19) United States
(12) Patent Application Publication
(10) Pub. No.: US 2020/0328365 A1
(43) Pub. Date: Oct. 15, 2020

(54) VEHICLE LAMPS

(71) Applicant: Ford Global Technologies, LLC, Dearborn, MI (US)

(72) Inventors: Paul Kenneth Dellock, Northville, MI (US); Harry Lobo, Canton, MI (US); Stuart C. Salter, White Lake, MI (US); David Brian Glickman, Southfield, MI (US); Aaron Bradley Johnson, Allen Park, MI (US)

(73) Assignee: Ford Global Technologies, LLC, Dearborn, MI (US)

(21) Appl. No.: 16/379,854

(22) Filed: Apr. 10, 2019

(51) Int. Cl. H01L 51/42; B60Q 1/26; F21V 13/08; H01L 51/50; H01L 51/00; H05B 33/02; H01L 21/02

(52) U.S. Cl. CPC H01L 51/426; B60Q 1/2661; F21V 13/08; H01L 51/502; H01L 2251/301; H01L 51/0077; H05B 33/02; H01L 21/02381; H01L 21/02197; H01L 51/0037

(57) ABSTRACT

A vehicle includes a body and a lamp assembly coupled to the body. The lamp assembly includes a housing and a first metal conductor coupled to the housing. A semiconductor layer is coupled to the first metal conductor, wherein the semiconductor layer includes a plurality of perovskites configured to emit light. A second conductor is coupled to the semiconductor layer and a lens is coupled to the housing.

### FIELD OF THE DISCLOSURE

The present disclosure generally relates to vehicle lamps, and more particularly to semiconductor vehicle lamps.

### BACKGROUND OF THE DISCLOSURE

Automotive regulations may only allow certain colors of lights to be utilized on vehicle exteriors. Perovskite-based semiconductor light sources often only can emit certain colors of light, which may not conform to local automotive regulations.

### SUMMARY OF THE DISCLOSURE

According to at least one aspect of the present disclosure, a vehicle includes a body and a lamp assembly coupled to the body. The lamp assembly includes a housing and a first metal conductor coupled to the housing. A semiconductor layer is coupled to the first metal conductor, wherein the semiconductor layer includes a plurality of perovskites configured to emit light. A second conductor is coupled to the semiconductor layer and a lens is coupled to the housing.

According to another aspect of the present disclosure, a vehicle exterior lamp includes a substrate and a first conductor coupled to the substrate. A semiconductor layer is coupled to the first conductor, wherein the semiconductor layer includes a plurality of perovskites configured to emit a first light. A second conductor is coupled to the semiconductor layer, wherein the second conductor includes a substantially transparent material. A photoluminescent element is coupled to the second conductor and configured to emit a second light in response to receiving the first light.

According to another aspect of the present disclosure, a method for manufacturing a lamp assembly for a vehicle includes steps of molding a housing, vacuum metalizing a first conductor on an inner surface of the housing, printing a semiconductor layer on the first conductor, printing a second conductor on the semiconductor layer, and printing a photoluminescent element on the second conductor.

These and other aspects, objects, and features of the present disclosure will be understood and appreciated by those skilled in the art upon studying the following specification, claims, and appended drawings.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

In the drawings:

FIG. 1A is a side view of a photoluminescent structure rendered as a coating according to one example;

FIG. 1B is a top view of a photoluminescent structure rendered as a discrete particle, according to one example;

FIG. 1C is a side view of a plurality of photoluminescent structures rendered as discrete particles and incorporated into a separate structure, according to one example;

FIG. 2 is a rear perspective view of a vehicle incorporating a vehicle lamp, according to one example;

FIG. 3 is an exploded view of a lighting element of the vehicle lamp of FIG. 2, according to one example;

FIG. 4 is a cross-sectional view taken along line IV-IV of FIG. 2 of the vehicle lamp, according to one example; and

FIG. 5 is a flow diagram of a method of manufacturing the vehicle lamp of FIG. 2.

### DETAILED DESCRIPTION OF THE PREFERRED EMBODIMENTS

Additional features and advantages of the invention will be set forth in the detailed description which follows and will be apparent to those skilled in the art from the description, or recognized by practicing the invention as described in the following description, together with the claims and appended drawings.

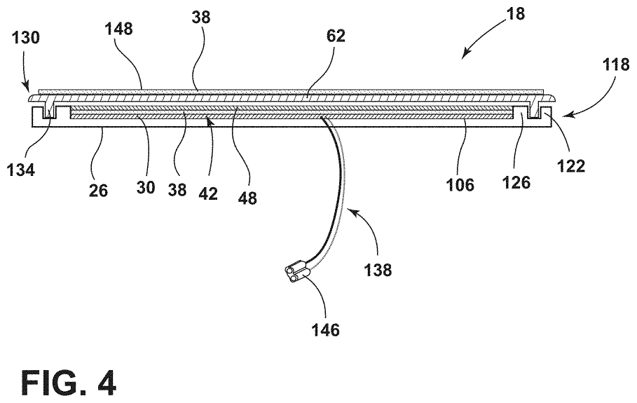

For purposes of description herein, the terms “upper,” “lower,” “right,” “left,” “rear,” “front,” “vertical,” “horizontal,” and derivatives thereof shall relate to the concepts as oriented in FIG. 4. However, it is to be understood that the concepts may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

As used herein, the term “and/or,” when used in a list of two or more items, means that any one of the listed items can be employed by itself, or any combination of two or more of the listed items, can be employed. For example, if a composition is described as containing components A, B, and/or C, the composition can contain A alone; B alone; C alone; A and B in combination; A and C in combination; B and C in combination; or A, B, and C in combination.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

In this document, relational terms, such as first and second, top and bottom, and the like, are used solely to distinguish one entity or action from another entity or action, without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

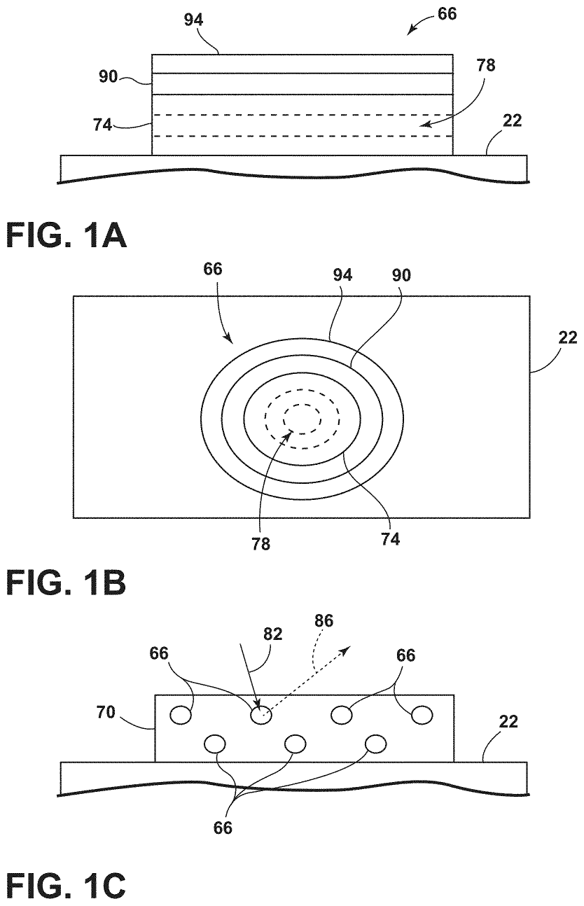

Referring to FIGS. 1A-5, reference numeral 10 generally refers to a vehicle having a body 14 and a lamp assembly 18. The lamp assembly 18 is coupled to the body 14 and includes a substrate 22, which may be a housing 26. A first conductor 30 is coupled to the substrate 22. A dielectric layer 34 may be coupled to the first conductor 30. A semiconductor layer 38 may be coupled to the first conductor 30 and/or the dielectric layer 34, wherein the semiconductor layer 38 includes a plurality of perovskites 42 configured to emit a first light 46. A second conductor 48 is coupled to the semiconductor layer 38. A photoluminescent element 50 may be coupled to the second conductor 48, wherein the photoluminescent element 50 is configured to emit the second light 54. A lens 62 may be coupled to the substrate 22 and/or the housing 26.

Referring to FIGS. 1A-1C, various exemplary embodiments of photoluminescent structures 66 are shown. Each photoluminescent structure 66 is capable of being coupled to the substrate 22, which may correspond to a vehicle fixture or vehicle-related piece of equipment. In FIG. 1A, the photoluminescent structure 66 is generally shown rendered as a coating (e.g., a film) that may be applied to a surface of the substrate 22. In FIG. 1B, the photoluminescent structure 66 is generally shown as a discrete particle capable of being integrated with the substrate 22. In FIG. 1C, the photoluminescent structure 66 is generally shown as a plurality of discrete particles that may be incorporated into a support medium 70 (e.g., a film) that may then be applied or integrated with the substrate 22.

In various examples, a given photoluminescent structure 66 includes an energy conversion layer 74 that may include one or more sublayers, which are exemplarily shown through broken lines in FIGS. 1A and 1B. Each sublayer of the energy conversion layer 74 may include one or more photoluminescent materials 78 having energy converting elements with phosphorescent, fluorescent, and/or energy converting properties. Each photoluminescent material 78 may become excited upon receiving an excitation light 82 of a specific wavelength, thereby causing the light to undergo a conversion process. Under the principle of down conversion, the excitation light 82 is converted into a longer wavelength, converted light 86, that is outputted from the photoluminescent structure 66. Conversely, under the principle of up conversion, the excitation light 82 is converted into a shorter wavelength, light, that is outputted from the photoluminescent structure 66. When multiple distinct wavelengths of light are outputted from the photoluminescent structure 66 at the same time, the wavelengths of light may mix together and be expressed as a multicolor light.

Light emitted by the sun, ambient sources, and/or light sources (e.g., the first light 46) which excites the photoluminescent material 78 is referred to herein as the excitation light 82, and is illustrated herein as solid arrows. In contrast, light emitted from the photoluminescent structure 66 is referred to herein as converted light 86 (e.g., the second light 54), and is illustrated herein as broken arrows. The mixture of excitation light 82 and converted light 86 that may be emitted simultaneously is referred to herein as outputted light.

The energy conversion layer 74 may be prepared by dispersing the photoluminescent material 78 in a polymer matrix to form a homogenous mixture using a variety of methods. Such methods may include preparing the energy conversion layer 74 from a formulation in a liquid carrier support medium 70 and coating the energy conversion layer 74 to a desired substrate 22. The support medium 70 may include an optically transparent or translucent material, such as polymethylmethacrylate, nylon, polycarbonate, polyester, polyvinyl chloride, other visually transparent materials, and/or combinations thereof. The energy conversion layer 74 may be applied to the substrate 22 by painting, screen-printing, spraying, slot coating, dip coating, roller coating, bar coating, and/or other application methods. Alternatively, the energy conversion layer 74 may be prepared by methods that do not use a liquid carrier support medium 70. For example, the energy conversion layer 74 may be rendered by dispersing the photoluminescent material 78 into a solid-state solution (homogenous mixture in a dry state) that may be incorporated in a polymer matrix, which may be formed by extrusion, injection molding, compression molding, calendaring, thermoforming, etc. The energy conversion layer 74 may then be integrated into the substrate 22 using any methods known to those skilled in the art. When the energy conversion layer 74 includes sublayers, each sublayer may be sequentially coated to form the energy conversion layer 74. Alternatively, the sublayers can be separately prepared and later laminated, or embossed, together to form the energy conversion layer 74. Alternatively still, the energy conversion layer 74 may be formed by coextruding the sublayers.

In some examples, the converted light 86 that has been down converted or up converted may be used to excite other photoluminescent materials 78 found in the energy conversion layer 74. The process of using the converted light 86 outputted from one photoluminescent material 78 to excite another, and so on, is generally known as an energy cascade and may serve as an alternative for achieving various color expressions. With respect to either conversion principle, the difference in wavelength between the excitation light 82 and the converted light 86 is known as the Stokes shift, and serves as the principal driving mechanism for an energy conversion process corresponding to a change in wavelength of light. In the various examples discussed herein, each of the photoluminescent structures 66 may operate under either conversion principle.

Referring again to FIGS. 1A and 1B, the photoluminescent structure 66 may optionally include at least one stability layer 90 to protect the photoluminescent material 78 contained within the energy conversion layer 74 from photolytic and thermal degradation. The stability layer 90 may be configured as a separate layer optically coupled and adhered to the energy conversion layer 74. Alternatively, the stability layer 90 may be integrated with the energy conversion layer 74. The photoluminescent structure 66 may also optionally include a protective layer 94 optically coupled and adhered to the stability layer 90, or other layer (e.g., a conversion layer 74 in the absence of the stability layer 90), to protect the photoluminescent structure 66 from physical and chemical damage arising from environmental exposure. The stability layer 90 and/or the protective layer 94 may be combined with the energy conversion layer 74 through sequential coating or printing of each layer, sequential lamination, or embossing, or any other suitable means.

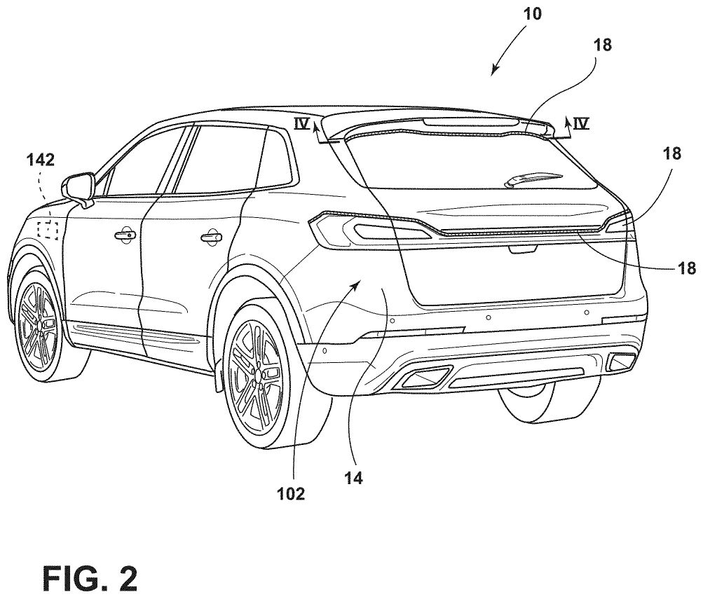

Referring to FIG. 2, the vehicle 10 may include the lamp assembly 18 coupled to a vehicle-rearward portion 102 of the body 14. The vehicle 10 is depicted as a sedan, but it will be understood that the vehicle 10 may be a truck, van, sport utility vehicle, cross-over, or other vehicle 10 without departing from the teachings provided herein. The vehicle 10 may include one or more lamp assemblies 18 positioned around the vehicle 10. For example, the lamp assembly 18 may be a center high mount stop lamp (CHMSL) or a decorative light bar. In examples where the lamp assembly 18 is the decorative light bar, the lamp assembly 18 may extend across an entire or a substantial portion of a width of the vehicle 10. In additional examples, the lamp assembly 18 may also be a tail lamp, a side marker, a headlight, a turn indicator lamp, a license plate lamp, a side mirror lamp, a bumper lamp, fog lamps, day time running lamps (DTRL), other Federal Motor Vehicle Safety Standard No. 108 (FMVSS-108) market lamps, rear fog lamps, S3 and S4 lamps, clearance lamps, dipped beams, other Economic Commission for Europe Regulation No. 48 (ECE-48) market lamps, reflex plates, other lamp assemblies 18, or combinations thereof.

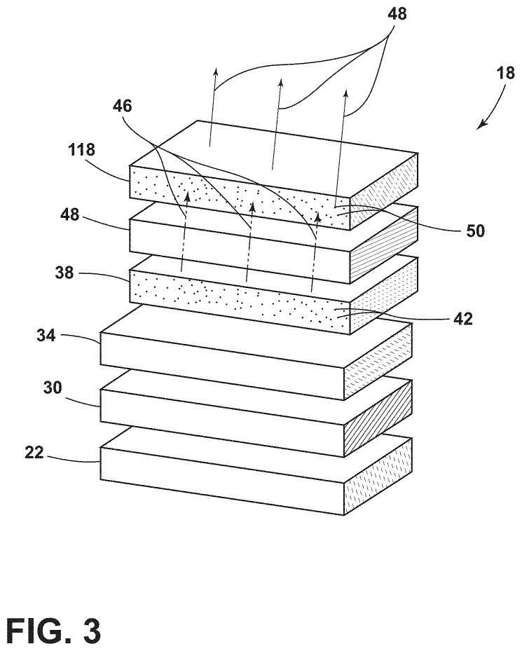

Referring now to FIG. 3, the lamp assembly 18 may include the substrate 22 on which other components of the lamp assembly 18 are positioned. In various examples, the substrate 22 may form the housing 26 (FIG. 4) for the lamp assembly 18. The substrate 22 may be composed of polymeric, metallic, and/or ceramic materials. According to various examples, the substrate 22 may include one or more dielectric materials (e.g., a silicon chip). In dielectric examples, the substrate 22 may include one or more oxides. For example, the substrate 22 may be composed of any of the materials outlined in connection with the dielectric layer 34. The substrate 22 may be a monolithic block, a film, or other thin sheet on which other components of the lamp assembly 18 are printed, or otherwise disposed.

The first conductor 30 is positioned on and/or coupled to the substrate 22. The first conductor 30 may be printed, deposited, adhered, or otherwise applied to the substrate 22. The first conductor 30 may be a metal, a transparent conductive oxide, a transparent conductive ink, or a semi-transparent conductive ink. In metallic examples, the first conductor 30 may include aluminum, silver, gold, copper, platinum, other conductive metals, and/or combinations thereof The first conductor 30 may form a vacuum metalized layer positioned on the substrate 22 and/or an inner surface 106 of the housing 26 (FIG. 4). In transparent conductive oxide examples, the first conductor 30 may include indium tin oxide, aluminum doped zinc oxide, barium stannate, indium zinc oxide, other transparent conductive oxides, and/or combinations thereof. In semi-transparent conductive oxide examples, the first conductor 30 may include silver inks, poly(3,4-ethylenedioxythiophene) (PEDOT), graphene, other conductive oxides, and/or combinations thereof. The first conductor 30 may, in various examples, include a metal mesh (e.g., silver nanowires) in a random or ordered orientation.

According to various examples, the dielectric layer 34 may be coupled to the first conductor 30. The dielectric layer 34 may be positioned between the first conductor 30 and the second conductor 48. It is contemplated that the dielectric layer 34 may be coupled to and/or be positioned above, below, or integrally defined with the semiconductor layer 38. The dielectric layer 34 may include silicon monoxide, silicon dioxide, silicon nitride, alkali halides (e.g., rubidium bromide, lithium fluoride, etc.), barium titanate, other dielectrics, and/or combinations thereof. The dielectric layer 34 may be a monolithic block, film, or other thin sheet. Further, the dielectric layer 34 may be printed, deposited, adhered, or otherwise applied to the first conductor 30 and/or the semiconductor layer 38.

Referring still to FIG. 3, the semiconductor layer 38 may be positioned on and/or coupled to the first conductor 30. According to various examples, the semiconductor layer 38 may include the plurality of quantum dots or perovskites 42 configured to emit the first light 46. In various examples, the lamp assembly 18 may include tripod quantum dots. As used herein, a perovskite 42 is any material with the same type of crystal structure as calcium titanium oxide (CaTiO3) or XIIA2+VIB4+X2-3 with an oxygen atom in the face centers of the crystal. The general chemical formula for perovskite compounds is ABX3, where A and B are two cations of very different sizes, and X is an anion that bonds to both. According to various examples, the A atoms are larger than the B atoms. According to various examples, a preferred cubic-symmetry structure has the B cation in 6-fold coordination, surrounded by an octahedron of anions, and the A cation in 12-fold cuboctahedral coordination.

The perovskite 42 examples of the semiconductor layer 38 are configured to emit the first light 46 in response to receiving electrical energy (i.e., in the form of current or voltage) from the first conductor 30 and the second conductor 48. In other words, the semiconductor layer 38 is configured to emit the first light 46 in response to an electrical potential being generated between the first conductor 30 and the second conductor 48. It will be understood that the perovskites 42 of the semiconductor layer 38 may emit the first light 46 in response to other forms of energy received without departing from the teachings provided herein. The perovskites 42 may tightly confine either electrons or electron holes in all three spatial dimensions and may be photoluminescent. Perovskites 42 may have a radius, or a distance half of their longest length, in the range of between about 1 nm and about 10 nm, or between about 2 nm and about 6 nm. Larger perovskites 42 (e.g., radius of from about 5 nm to about 6 nm) may emit the first light 46 having a longer wavelength light, resulting in the color of the light being such colors as orange or red. Smaller perovskites 42 (e.g., radius of from about 2 nm to about 3 nm) may emit the first light 46 having a shorter wavelength light, resulting in colors such as blue or green. Exemplary compositions of the perovskites 42 may include LaF3 nanocrystals that are doped (e.g., coated) with Yb—Er, Yb—Ho, and/or Yb—Tm. In yet other examples, the perovskites 42 may be CsPb crystals including Cl, Br, I and may generally have the formula CsPb(Cl/Br)2, CsPbBr3, CsPb(I/Br)3, and/or CsPbI3. In yet other examples, the perovskites 42 may include In, Sn, Cd, I, InP/ZnS, and/or CuInS/ZnS. It will be understood that other types of perovskites 42 may be utilized.

In various examples, the perovskites 42 may have an emission line width of about 100 nm or less, about 95 nm or less, about 90 nm or less, about 85 nm or less, about 80 nm or less, about 75 nm or less, about 70 nm or less, about 65 nm or less, about 60 nm or less, about 55 nm or less, about 50 nm or less, about 45 nm or less, about 40 nm or less, about 35 nm or less, about 30 nm or less, about 25 nm or less, about 20 nm or less, about 15 nm or less, about 10 nm or less, about 5 nm or less, or any and all values and ranges there between.

The perovskites 42 may be introduced into the semiconductor layer 38 in a variety of manners. In a first method, the perovskites 42 may be blended directly into a binder. Next, the mixture of the perovskites 42 and the binder may be extruded into the semiconductor layer 38 and positioned on the lamp assembly 18. Another exemplary method of coupling the perovskites 42 and the semiconductor layer 38 is to apply a thin coating of the perovskites 42 to a surface of the semiconductor layer 38. To do this, the perovskites 42 are first blended into a polymer or a polymerizable mixture of monomers. Next, the mixture is then spin coated, ink jetted, screen printed, and/or otherwise applied as a thin layer over a surface of the semiconductor layer 38. Monomer mixtures can be polymerized (e.g., cured) on the surface after application. Using this approach, it may be important to assure that the polymer or monomer mixture is lipophilic (e.g., non-polar) if organic soluble perovskites 42 are being used. Conversely, if water-soluble perovskites 42 are being used, the polymer or monomers may be hydrophilic (e.g., water soluble). It will be understood that various inks, dyes, pigments, or colorants may be added to the perovskites 42. It is also contemplated that the perovskites 42 may be applied as an aqueous, liquid, paste, and/or powder form to the dielectric layer 34.

The second conductor 48 is positioned on and/or coupled to the semiconductor layer 38. The second conductor 48 may be printed, deposited, adhered, or otherwise applied to the substrate 22. The second conductor 48 may be a metal, a transparent conductive oxide, a transparent conductive ink, or a semi-transparent conductive ink. In metallic examples, the second conductor 48 may include aluminum, silver, gold, copper, platinum, other conductive metals, and/or combinations thereof. In transparent conductive oxide examples, the second conductor 48 may include indium tin oxide, aluminum doped zinc oxide, barium stannate, indium zinc oxide, nickel oxide, tungsten oxide, other transparent conductive oxides, and/or combinations thereof. In various examples, the second conductor 48 may include a substantially transparent material to allow the first light 46 emitted from the semiconductor layer 38 to be visible through the second conductor 48. In semi-transparent conductive oxide examples, the second conductor 48 may include silver inks, poly(3,4-ethylenedioxythiophene) (PEDOT), graphene, other conductive oxides, and/or combinations thereof. The first conductor 30 may, in various examples, include a metal mesh (e.g., silver nanowires) in a random or ordered orientation. In some examples, the first and second conductors 30, 48 may include the same material, and in other examples the first and second conductors 30, 48 may include different materials.

Referring still to FIG. 3, a polymeric layer 118 may be positioned on the second conductor 48. The polymeric layer 118 may include an optically transparent or translucent material, such as polymethylmethacrylate, nylon, polyether ether ketone, polycarbonate, polyester, polyvinyl chloride, other visually transparent materials, and/or combinations thereof The polymeric layer 118 may include, be infused with, or otherwise be coupled with the photoluminescent element 50 (e.g., one or both of the photoluminescent materials 78 and the photoluminescent structure 66 as outlined above). In other words, the photoluminescent element 50 is coupled to the second conductor 48. For example, the photoluminescent element 50 may be mixed into or otherwise dispersed into the polymeric layer 118. Additionally or alternatively, the photoluminescent element 50 may be deposited as a coating or thin film on a surface of, or within, the polymeric layer 118. The photoluminescent element 50 of the polymeric layer 118 may include one or more rylene family of dyes (e.g., boron-dipyrromethene), other photoluminescent compounds, and/or combinations thereof. It will be understood that the photoluminescent element 50 may uniformly extend across the polymeric layer 118 or in a discontinuous manner. Further, the photoluminescent element 50 may form an indicia (e.g., alpha-numeric text, symbols, pictures, images, etc.).

The photoluminescent element 50 of the polymeric layer 118 is configured to receive the first light 46 (e.g., the excitation light 82) emitted by the semiconductor layer 38 and emit the second light 54 (e.g., the converted light 86) in response. According to various examples, the wavelength of the first light 46 is shorter than the wavelength of the second light 54. In other words, the wavelength of the second light 54 is longer than the wavelength of the first light 46. According to various examples, the photoluminescent element 50 may be configured to emit visible light having a wavelength of from about 400 nm to about 750 nm. For example, the photoluminescent element 50 may emit light having a wavelength of from about 380 nm to about 450 nm generally corresponding to violet light, from about 450 nm to about 495 nm generally corresponding to blue light, from about 495 nm to about 570 nm generally corresponding to green light, from about 570 nm to about 590 nm generally corresponding to yellow light, from about 610 nm to about 620 nm generally corresponding to orange light, and/or from about 620 nm to about 750 nm generally corresponding to red light. As such, the photoluminescent element 50 may be configured to emit the second light 54 having a wavelength range of from about 600 nm to about 750 nm in response to receiving the first light 46.

The polymeric layer 118, including the photoluminescent element 50, may be substantially transparent to visible light. For example, the polymeric layer 118, including the photoluminescent element 50, may have a transmittance at a wavelength of about 530 nm of about 40% or greater, about 45% or greater, about 50% or greater, about 55% or greater, about 60% or greater, about 65% or greater, about 70% or greater, about 75% or greater, about 80% or greater, about 85% or greater, about 90% or greater, about 95% or greater, about 96% or greater, about 97% or greater, about 98% or greater, about 99%, or greater or any and all values and ranges therebetween.

In operation, the photoluminescent element 50 of the polymeric layer 118 may be utilized to shift the color of light emitted from the lamp assembly 18 to a different color of light than that is produced by the semiconductor layer 38 as the first light 46. For example, the perovskites 42 of the semiconductor layer 38 may be configured to emit the first light 46 in a wavelength range of from about 495 nm to about 570 nm. The first light 46 is transmitted through the second conductor 48 and into the polymeric layer 118. The photoluminescent element 50 of the polymeric layer 118 is configured to absorb the first light 46 and Stokes shift (i.e., Stokes shifts can be performed by a molecule that can absorb a photon of shorter wavelength (higher frequency or energy) and emit a longer-wavelength photon) the wavelength of the first light 46 into a longer wavelength of the second light 54 emitted by the photoluminescent element 50. For example, the photoluminescent element 50 may emit the second light 54 at a wavelength range of from about 600 nm to about 750 nm, or from about 610 nm to about 620 nm. Such a feature of Stokes shifting between the first light 46 and the second light 54 may be advantageous in that the human eye is more sensitive to shades of red that have shorter wavelengths than those of longer wavelengths. Further, the red and/or orange shades of the second light 54 (e.g., from about 610 nm to about 620 nm wavelength) may meet legal requirements for vehicle exterior lamp assemblies 18.

Referring now to FIG. 4, a cross-sectional view of the lamp assembly 18 as outlined above is depicted. In various example, the substrate 22 (FIG. 1A) may form the housing 26 of the lamp assembly 18. Each lateral edge portion 120 of the housing 26 defines an outer protrusion 122 spaced apart from an inner protrusion 126. The first conductor 30, the semiconductor layer 38, the dielectric layer 34, and/or the second conductor 48 are coupled to the housing 26 between the inner protrusions 126. According to various examples, the first conductor 30 may be selectively coated with the semiconductor layer 38 and/or the perovskites 42. Alternatively, the entirety of the first conductor 30 may be coated with the perovskites 42.

As illustrated, the lens 62 is positioned over the first and second conductors 30, 48 and the semiconductor layer 38 and is coupled to the housing 26. Outer edge portions 130 of the lens 62 each define a projection 134 configured to be positioned between the outer and inner protrusions 122, 126 of the housing 26 for coupling the lens 62 to the housing 26. The lens 62 may include any material of any refractive index that will allow light to pass though, such as, for example, optical polycarbonate, acrylic, polymethyl methacrylate, a reflex cube array, or combinations thereof. The material utilized in the lens 62 may produce a desired lighting effect based on a refractive index for altering light direction of the chosen material. Different materials may also be advantageous to reduce manufacturing and production costs. In various examples, a diffusing layer 148 may be applied to the lens 62. The diffusing layer 148 may contribute to and/or provide for a substantially uniform appearance of the emitted first and/or second light 46, 54 (FIG. 3). In some examples, the diffusing layer 148 may be a texture or a layer applied to the lens 62, and in other examples, the diffusing layer 148 may be integrally formed with the lens 62. Additionally or alternatively, the diffusing layer 148 may include perovskites 38 embedded or otherwise provided in the diffusing layer 148.

An electrical connection 138 (e.g., wiring) may be coupled to the first conductor 30. The electrical connection 138 may operate to ground the first conductor 30 to the body 14, or a power source 142 of the vehicle 10 (FIG. 1). The electrical connection 138 may also include a connector 146 and/or wiring harness. Additionally, the electrical connection 138 may be coupled to the second conductor 48. In such example, the second conductor 48 may carry the positive voltage through the lamp assembly 18, and the first conductor 30 may carry negative voltage to complete the electrical circuit and generate the electrical potential for the semiconductor layer 38 therebetween. It is also contemplated that the lamp assemblies 18 may include one or more housings 26, lenses 62, covers, and/or shields in order to direct the second light 54 (FIG. 3), and/or to produce an aesthetically pleasing appearance to the vehicle 10 (FIG. 1).

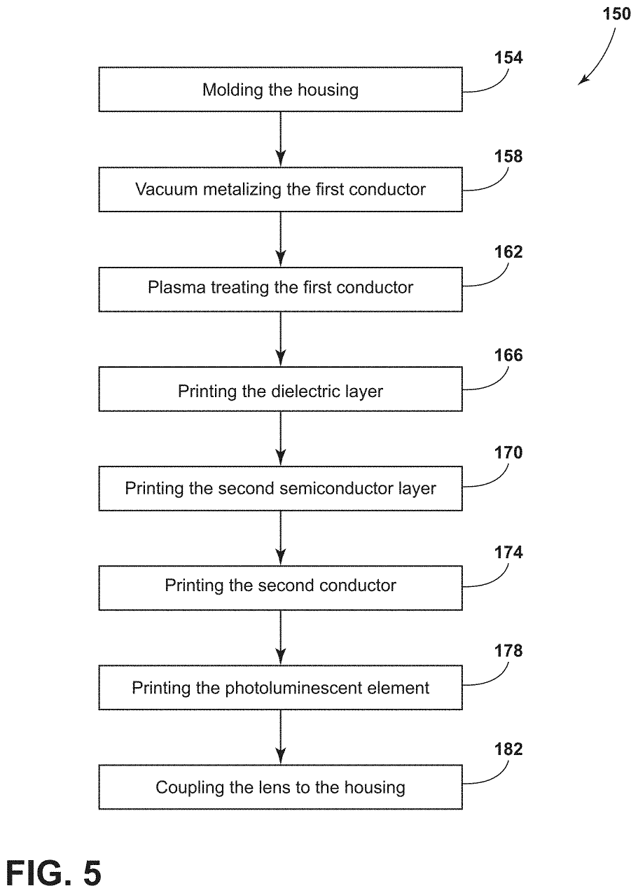

Referring now to FIG. 5, and with further reference to FIGS. 1A-4, and with further reference to FIGS. 1A-4, a method 150 for manufacturing the lamp assemblies 18 begins with a step 154 of molding the housing 26. The housing 26 may be formed by, for example, injection molding or a similar molding process. The housing 26 may be formed into any shape depending on the type of vehicle lamp assembly 18 desired.

A next step 158 includes vacuum metalizing the first conductor 30 on the inner surface 106 of the housing 26. Vacuum metalizing allows a layer of metal, such as the first conductor 30, to be deposited on the housing 26 and/or substrate 22. The metal is heated in a vacuum chamber until it vaporizes and can then be applied to the substrate 22. The first conductor 30 may also be coupled to the housing 26 and/or substrate 22 via any other physical vapor deposition process.

Next, a step 162 includes plasma treating the first conductor 30. Plasma treating operates to clean the first conductor 30 of particulates that may affect bonding with other components of the lamp assembly 18. For example, the plasma treating may allow for better adhesion between the first conductor 30 and the semiconductor layer 38.

The method 150 may also include a step 166 of printing the dielectric layer 34 on the first conductor 30 and/or the semiconductor layer 38. The dielectric layer 34 may be printed over the entire first conductor 30 or a portion of the first conductor 30. The printing process may include laser jet printing, silk screen printing, other printing processes, or a combination thereof.

Next, a step 170 includes depositing and/or printing the semiconductor layer 38 including the plurality of perovskites 42. As outlined above, the perovskites 42 may be blended directly into a binder, or applied to a surface of the semiconductor layer 38 by being first blended into a polymer. The printing process may include laser jet printing, silk screen printing, other printing processes, or a combination thereof.

The method 150 also includes a step 174 of printing the second conductor 48 on the semiconductor layer 38. The second conductor 48 may be printed over the entire semiconductor layer 38, or a portion of the semiconductor layer 38. The printing process may include laser jet printing, silk screen printing, other printing processes, or a combination thereof.

According to various examples, the method 150 includes a step 178 of printing the photoluminescent element 50 on a second conductor 48. As outlined above, the photoluminescent element 50 may be mixed into, or otherwise dispersed into, the polymeric layer 118 or may be deposited as a coating or thin film on a surface of, or within the polymeric layer 118. The printing process may include laser jet printing, silk screen printing, other printing processes, or a combination thereof.

Next, a step 182 includes coupling the lens 62 to the housing 26. This step 182 may also include molding the lens 62 via injection molding or another molding process. The lens 62 may be coupled to the housing 26 via sonic welding, hot plate welding, laser welding, or otherwise adhering the lens 62 to the housing 26.

Use of the present disclosure may offer a variety of advantages. For example, use of the presently disclosed lamp assembly 18 may achieve greater than 50% transparency of the polymeric layer 118 in addition to an efficiency of at least 10% (i.e., in Stokes shifting of the first light 46 to the second light 54), which yields about 30 cd/m2 light output which is adequate for automotive lighting applications. Additionally, the presently disclosed lamp assembly 18 may form a continuous lighting element having a substantially even appearance with minimal and/or no concentrated lighting portions (e.g., hot spots). Further, lamp assemblies 18 of the present disclosure may be thinner than conventional light sources and offer visual styling effects similar to conventional organic light emitting diode light sources.

According to various examples a vehicle lamp includes a substrate and a first metal conductor coupled to the substrate. A dielectric layer is coupled to the first metal conductor. A semiconductor layer is coupled to the dielectric layer, wherein the semiconductor layer includes a plurality of perovskites. A second conductor is coupled to the semiconductor layer. Embodiments of the present disclosure may include one or a combination of the following features:
the lamp assembly includes a center high mount stop lamp;
the lamp assembly includes a decorative light bar coupled to a vehicle-rearward portion of a body of a vehicle;
the first metal conductor comprises a vacuum metalized layer positioned on an inner surface of a housing;
an electrical connection couples the first conductor to at least one of the body of the vehicle and a power source;
the semiconductor layer is configured to emit light in response to an electrical potential being generated between the first metal conductor and the second conductor;
the second conductor includes at least one of indium tin oxide, aluminum doped zinc oxide, nickel oxide, tungsten oxide, and silver nanowires;
a polymeric layer comprising a photoluminescent element, wherein the plurality of perovskites are configured to emit a first light and the photoluminescent element is configured to emit a second light;
the second light comprises light having a longer wavelength than the first light;
the substrate comprises a lamp housing;
the first metal conductor comprises at least one of aluminum, silver, copper, and gold;
the second conductor comprises a transparent oxide;
the photoluminescent element comprises boron-dipyrromethene;
the first light comprises light of a wavelength range of from about 495 nm to about 570 nm;
the second light comprises light of a wavelength of a range of from about 600 nm to about 750 nm;
the plurality of perovskites comprise at least one of indium, tin, cadmium and iodine; and
the second light comprises light of a wavelength of a range of from about 610 nm to about 620 nm.

According to various examples, a method for manufacturing a lamp assembly for a vehicle includes steps of molding a housing, vacuum metalizing a first conductor on an inner surface of the housing, printing a semiconductor layer on the first conductor, printing a second conductor on the semiconductor layer, and printing a photoluminescent element on the second conductor. Embodiments of the present disclosure may include one or a combination of the following features:
plasma treating the first conductor; and
coupling a lens to the housing.

Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims, as interpreted according to the principles of patent law, including the doctrine of equivalents.

It is to be understood that variations and modifications can be made on the aforementioned structure without departing from the concepts of the present disclosure, and further it is to be understood that such concepts are intended to be covered by the following claims unless these claims by their language expressly state otherwise.

What is claimed is:

1. A vehicle, comprising:
a body; and
a lamp assembly coupled to the body, the lamp assembly comprising:
a housing;
a first metal conductor coupled of the housing;
a semiconductor layer coupled to the first metal conductor, wherein the semiconductor layer comprises a plurality of perovskites configured to emit light;
a second conductor coupled to the semiconductor layer; and
a lens coupled to the housing.

2. The vehicle of claim 1, wherein the lamp assembly comprises a center high mount stop lamp.

3. The vehicle of claim 1, wherein the lamp assembly comprises a decorative light bar coupled to a vehicle-rearward portion of the body.

4. The vehicle of claim 1, wherein the first metal conductor comprises a vacuum metalized layer positioned on an inner surface of the housing.

5. The vehicle of claim 1, wherein an electrical connection couples the first conductor to at least one of the body and a power source.

6. The vehicle of claim 1, wherein the semiconductor layer is configured to emit light in response to an electrical potential being generated between the first metal conductor and the second conductor.

7. The vehicle of claim 1, wherein the second conductor comprises at least one of indium tin oxide, aluminum doped zinc oxide, nickel oxide, tungsten oxide, and silver nanowires.

8. A vehicle lamp, comprising:
a substrate;
a first conductor coupled to the substrate;
a semiconductor layer coupled to the first conductor, wherein the semiconductor layer comprises a plurality of perovskites configured to emit a first light;
a second conductor coupled to the semiconductor layer, wherein the second conductor comprises a substantially transparent material; and
a photoluminescent element coupled to the second conductor and configured to emit a second light in response to receiving the first light.

9. The vehicle lamp of claim 8, further comprising:
a polymeric layer comprising the photoluminescent element, wherein the plurality of perovskites are configured to emit a first light and the photoluminescent element is configured to emit a second light.

10. The vehicle lamp of claim 9, wherein the second light comprises light having a longer wavelength than the first light.

11. The vehicle lamp of claim 8, wherein the substrate comprises a lamp housing.

12. The vehicle lamp of claim 8, wherein the first metal conductor comprises at least one of aluminum, silver, copper, and gold.

13. The vehicle lamp of claim 8, wherein the semiconductor layer is configured to emit light in response to an electrical potential being generated between the first conductor and the second conductor.

14. The vehicle lamp of claim 8, wherein the second conductor comprises a transparent oxide.

15. The vehicle lamp of claim 8, wherein the photoluminescent element comprises boron-dipyrromethene.

16. The vehicle lamp of claim 8, wherein the first light comprises light of a wavelength range of from about 495 nm to about 570 nm.

17. The vehicle lamp of claim 8, wherein the second light comprises light of a wavelength of a range of from about 600 nm to about 750 nm.

18. The method of manufacturing a lamp assembly for a vehicle, comprising the steps of:
molding a housing;
vacuum metalizing a first conductor on an inner surface of the housing;
printing a semiconductor layer on the first conductor;
printing a second conductor on the semiconductor layer; and
printing a photoluminescent element on the second conductor.

19. The method of manufacturing a lamp assembly for a vehicle of claim 18, further comprising the step of:
plasma treating the first conductor.

20. The method of manufacturing a lamp assembly for a vehicle of claim 18, further comprising the step of:
coupling a lens to the housing.
